(19) United States
(12) Patent Application Publication
(10) Pub. No.: US 2025/0363613 A1
(43) Pub. Date: Nov. 27, 2025

(54) RECORDING MEDIUM, DATA GENERATION METHOD, LEARNING MODEL GENERATION METHOD, AND INFORMATION PROCESSING DEVICE FOR GENERATING EXPANSION DATA BASED ON A FRAME IMAGE OF A FIRST TIME POINT AND A FRAME IMAGE OF A SECOND TIME POINT LATER THAN THE FIRST TIME POINT, WHICH ARE INCLUDED IN AN ACQUIRED MOVING IMAGE

(71) Applicant: Tokyo Electron Limited, Tokyo (JP)

(72) Inventor: Ruiki KOBAYASHI, Koshi City (JP)

(73) Assignee: Tokyo Electron Limited, Tokyo (JP)

(21) Appl. No.: 19/217,382

(22) Filed: May 23, 2025

(30) Foreign Application Priority Data
May 27, 2024 (JP) 2024-085786

(51) Int. Cl. G06T 7/00; G06T 7/246; G06V 10/764; G06V 10/774

(52) U.S. Cl. CPC G06T 7/0004; G06T 7/248; G06V 10/7747; G06T 2207/20081; G06T 2207/20216; G06T 2207/30148; G06V 10/764

(57) ABSTRACT

A non-transitory computer-readable recording medium having stored thereon a computer program that, in response to execution, causes circuitry to perform a method including: acquiring a moving image of a substrate processing apparatus; and generating expansion data based on a frame image of a first time point and a frame image of a second time point later than the first time point, which are included in the acquired moving image.

### CROSS-REFERENCE TO RELATED APPLICATION

This application claims the benefit of Japanese Patent Application No. 2024-085786, filed on May 27, 2024, the entire contents of which is incorporated herein by reference.

### TECHNICAL FIELD

The various aspects and embodiments described herein pertain generally to a recording medium, a data generation method, a learning model generation method, and an information processing device.

### BACKGROUND

Patent document 1 proposes a substrate processing method that includes a holding process of carrying a substrate into a chamber and holding it, a supply process of supplying a fluid to the substrate inside the chamber, an imaging process of sequentially imaging the inside of the chamber with a camera to acquire image data, a condition setting process of identifying a monitoring target from multiple monitoring target candidates inside the chamber and changing image conditions based on the monitoring target, and a monitoring process of performing a monitoring processing on the monitoring target based on the image data having the image conditions corresponding to the monitoring target.
Patent Document 1: Japanese Patent-Laid open Publication No. 2021-190511

### SUMMARY

In an exemplary embodiment, there is provided a computer-readable recording medium having stored thereon a computer program that, in response to execution, causes a computer to perform: acquiring a moving image of a substrate processing; and generating expansion data based on a frame image of a first time point and a frame image of a second time point later than the first time point, which are included in the acquired moving image.

### BRIEF DESCRIPTION OF THE DRAWINGS

FIG. 1 is a schematic diagram for describing a configuration example of a substrate processing apparatus according to an exemplary embodiment;

FIG. 2 is a schematic diagram for describing an outline of an information processing system according to the exemplary embodiment;

FIG. 3 is a block diagram illustrating a configuration example of an information processing device according to the exemplary embodiment;

FIG. 4 is a schematic diagram for describing data expansion performed by the information processing device according to the exemplary embodiment;

FIG. 5 is a schematic diagram illustrating an example of a label information input screen displayed by the information processing device according to the exemplary embodiment;

FIG. 6 is a flowchart showing an example sequence of a training data generation processing performed by the information processing device according to the exemplary embodiment;

FIG. 7 is a schematic diagram illustrating a configuration example of a learning model generated by the information processing device;

FIG. 8 is a flowchart showing an example sequence of the learning model generation processing performed by the information processing device according to the exemplary embodiment; and

FIG. 9 is a schematic diagram illustrating a configuration example of a learning model generated by the information processing device according to a second exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Specific examples of an information processing system according to exemplary embodiments of the present disclosure will be described below with reference to the accompanying drawings. Here, it should be noted that the present disclosure is not limited to these exemplary embodiments, but is defined by the scope of the claims, and it is intended that all modifications within the meaning and scope equivalent to the scope of the claims are included.

### First Exemplary Embodiment

### <System Configuration>

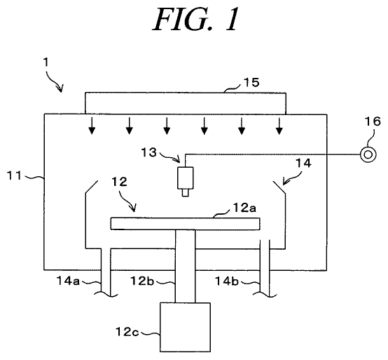

FIG. 1 is a schematic diagram illustrating a configuration example of a substrate processing apparatus 1 according to an exemplary embodiment. The substrate processing apparatus 1 according to the present exemplary embodiment is an apparatus that performs a substrate processing, so-called wet etching, of processing a substrate (for example, a wafer on which an oxide film or nitride film is formed) as a processing target into a required shape by supplying the film with a chemical liquid that dissolves the film, while rotating the substrate. The substrate processing apparatus 1 according to the exemplary embodiment includes a chamber 11, a substrate holding mechanism 12, a discharger 13, a recovery cup 14, and so forth.

The chamber 11 is a hermetically sealed reaction vessel, and houses therein the substrate holding mechanism 12, the discharger 13, the recovery cup 14, and the like. A fan filter unit (FFU) 15 is provided on a ceiling of the chamber 11. The FFU 15 forms a downflow inside the chamber 11.

The substrate holding mechanism 12 has a holder 12a, a supporting column 12b, and a driver 12c. The holder 12a is of, for example, a disk shape, and holds a substrate (wafer) as a processing target horizontally on the disk. The supporting column 12b is a cylindrical member connected to a central portion of a bottom surface of the holder 12a and extending in a vertical direction (up-and-down direction in FIG. 1), and is configured to support the holder 12a horizontally. A lower end of the supporting column 12b is connected to the driver 12c, and is rotatably supported by the driver 12c. The driver 12c has a prime mover such as a motor, and is configured to rotate the supporting column 12b around its axis. With this configuration, the substrate holding mechanism 12 may rotate the holder 12a supported by the supporting column 12b by rotating the supporting column 12b with the driver 12c, thus allowing the substrate held by the holder 12a to be rotated.

The discharger 13 is configured to discharge a liquid such as a chemical liquid or a cleaning liquid onto the substrate held by the substrate holding mechanism 12. By way of example, dilute hydrofluoric acid is used as the chemical liquid, and pure water is used as the cleaning liquid. However, the liquids discharged by the discharger 13 are not limited thereto. The discharger 13 is connected via, for example, a tube-shaped liquid supply path to a liquid supply source 16 provided outside the chamber 11, and is configured to discharge the liquid supplied from the supply source 16 onto the substrate. Further, the discharger 13 is connected to a driving mechanism, and is movable horizontally between a central portion and a peripheral portion of the substrate. By combining the rotation of the substrate by the substrate holding mechanism 12 and the horizontal movement of the discharger 13 by the driving mechanism, the substrate processing apparatus 1 is capable of discharging the liquid from the discharger 13 to an appropriate position on the processing target substrate.

The recovery cup 14 is configured to surround the holder 12a of the substrate holding mechanism 12, and serves to collect the liquid scattered from the substrate due to the rotation of the holder 12a. A drain port 14a is provided at a bottom of the recovery cup 14, and the liquid collected by the recovery cup 14 is drained from the drain port 14a to the outside of the chamber 11. An exhaust port 14b is provided at the bottom of the recovery cup 14, and a gas supplied from the FFU 15 is exhausted from the exhaust port 14b to the outside of the chamber 11.

The substrate processing apparatus 1 shown in FIG. 1 has a configuration in which only one discharger 13 for discharging the liquid is provided. The substrate processing apparatus 1 is capable of selectively discharging either the chemical liquid for performing a dissolving processing for the substrate or the cleaning liquid for cleaning the substrate by switching the chemical liquid and the cleaning liquid in the supply source 16. However, the substrate processing apparatus 1 may have a configuration including a plurality of dischargers 13. The substrate processing apparatus 1 may be equipped with, for example, a discharger 13 for discharging the chemical liquid and a discharger 13 for discharging the cleaning liquid.

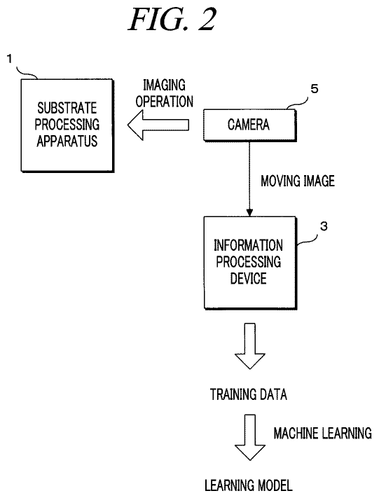

FIG. 2 is a schematic diagram illustrating an outline of an information processing system according to the exemplary embodiment. The information processing system according to the exemplary embodiment includes the above-described substrate processing apparatus 1, an information processing device 3, and a camera 5. The camera 5 includes an imaging element such as a charge coupled device (CCD) or a complementary metal oxide semiconductor (CMOS), and is capable of performing so-called moving image recording by performing imaging operations several tens of times per second. The camera 5 is disposed, for example, inside the chamber 11 of the substrate processing apparatus 1, and is configured to image the discharger 13 during the substrate processing. The camera 5 sends moving image data obtained by this imaging operation to the information processing device 3. The moving image data is, for example, data in which multiple still images (frame images) are arranged in time series. The camera 5 may be, for example, a device belonging to the substrate processing apparatus 1, or may be provided as a separate device from the substrate processing apparatus 1.

The information processing device 3 is a device that performs, based on the data of the moving image taken by the camera 5, a processing of generating training data for machine learning and generating a learning model by machine learning using this training data. In the present exemplary embodiment, the information processing device 3 is provided as a separate device from the substrate processing apparatus 1, but is not limited thereto and may be integrated with the substrate processing apparatus 1. The information processing device 3 is connected to the camera 5 via, for example, a communication cable, and can transceive data to/from the camera 5. The information processing device 3 receives the data of the moving image of the discharger 13 transmitted by the camera 5, and stores and accumulates the received moving image data in a storage.

The information processing device 3 according to the present exemplary embodiment generates training data for generating a learning model that determines a state related to the discharge of the liquid by the discharger 13 based on frame images that are included in the moving image acquired and accumulated from the camera 5. Here, based on the frame images included in the moving image taken by the camera 5, the information processing device 3 according to the present exemplary embodiment generates a frame image not included in this moving image, that is, performs so-called data expansion, thereby increasing frame images for use in machine learning. For example, the information processing device 3 receives from a user an input of label information indicating the discharge state of the discharger 13 for each frame image, and a set of data in which each frame image is matched with the corresponding label information is used as training data for so-called supervised machine learning.

In addition, when the information processing device 3 generates training data for so-called non-supervised machine learning, the reception of the input of the label information and the matching of each frame image with the corresponding label information may not need to be performed. In this case, the information processing device 3 uses a dataset including a frame image included in the moving image taken by the camera 5 and a frame image generated by expanding this frame image as training data.

Further, the information processing device 3 performs a processing of generating a learning model by performing a machine learning processing using the generated training data. By way of example, when the training data is the one in which the frame image and the label information are matched, the information processing device 3 may perform supervised machine learning, and receive the frame image as an input and generate a learning model for classifying the discharge state of the discharger 13 of the substrate processing apparatus 1 captured in the frame image. The learning model generated by the information processing device 3 is mounted on, for example, a control device that controls the operation of the substrate processing apparatus 1, and the control device acquires the moving image of the discharger 13 of the substrate processing apparatus 1 taken by the camera 5. The control device may input the frame image included in the acquired moving image into the learning model, acquire a classification result of the discharge state output by the learning model, and perform a control processing such as stopping the substrate processing of the substrate processing apparatus 1 when the acquired classification result indicates, for example, occurrence of an abnormality.

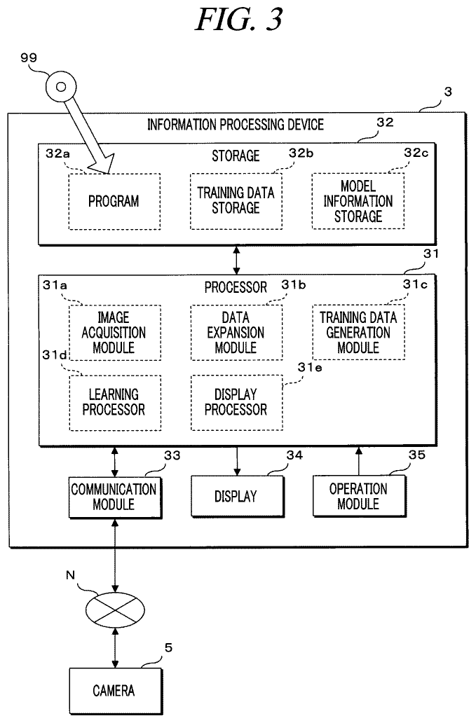

FIG. 3 is a block diagram illustrating a configuration example of the information processing device 3 according to the present exemplary embodiment. The information processing device 3 according to the present exemplary embodiment may be implemented by installing a preset application program or the like in a general-purpose information processing device such as, but not limited to, a personal computer or a server computer. The information processing device 3 according to the exemplary embodiment includes a processor 31, a storage 32, a communication module 33, a display 34, an operation module 35, and the like. In the present exemplary embodiment, the processing is performed by the single information processing device 3. However, the processing of the information processing device 3 may be performed by a plurality of devices in a distributed manner.

The processor 31 is composed of a processing module such as a central processing unit (CPU), a micro-processing unit (MPU), a graphics processing unit(GPU), or a quantum processor, and also includes a read only memory (ROM), a random access memory (RAM), and the like. The processor 31 reads out and executes a program 32a stored in the storage 32, thereby performing various processes, such as a processing of generating training data for performing machine learning based on the moving image acquired from the camera 5 and a processing of generating a learning model through machine learning using the generated training data.

The storage 32 is composed of a large-capacity storage device such as, but not limited to, a hard disk or a solid state drive (SSD). The storage 32 stores various types of programs to be executed by the processor 31, and various data necessary for the processing of the processor 31. In the present exemplary embodiment, the storage 32 stores the program 32a to be executed by the processor 31. In addition, the storage 32 is provided with a training data storage 32b that stores the generated training data, and a model information storage 32c that stores information about the generated learning model.

In the present exemplary embodiment, the program (a computer program or a program product) 32a is provided in a form recorded on a recording medium 99 such as a memory card or an optical disk, and the information processing device 3 reads the program 32a from the recording medium 99 and stores it in the storage 32. However, the program 32a may be written into the storage 32 in the manufacturing stage of the information processing device 3, for example. As another example, the information processing device 3 may acquire, through communication, the program 32a transmitted by a remote server device or the like. By way of example, a write device may read the program 32a recorded on the recording medium 99 and write it into the storage 32 of the information processing device 3. The program 32a may be provided in a form to be transmitted via a network, or may be provided in a form recorded on the recording medium 99.

The training data storage 32b stores the training data that is generated by the information processing device 3 based on the moving image taken by the camera 5. The training data is, for example, data in which a frame image is matched with label information indicating the discharge state of the discharger 13. The model information storage 32c stores information about a learning model that has been machine learning-trained. The information about the learning model may include, by way of example, information indicating a configuration of the learning model, information such as internal parameter values determined by the machine learning, and so forth.

In addition, in the present exemplary embodiment, the generation of the training data and the generation of the learning model are both performed by the information processing device 3, but the present disclosure is not limited thereto. The generation of the training data and the generation of the learning model may be performed by different devices. The device that generates the training data may transmit the training data to the device that generates the learning model, and the device that generates the learning model may receive this training data and perform the machine learning processing.

The communication module 33 performs transmission/reception of data to/from the camera 5 via, for example, a wired or wireless network N. In the present exemplary embodiment, the communication module 33 receives the moving image data transmitted from the camera 5 and provides it to the processor 31. In addition, the communication module 33 may also transmit, for example, a command to control the operation of the camera 5 to the camera 5 based on the information provided from the processor 311.

The display 34 is composed of a liquid crystal display or the like, and displays various types of images and characters based on the processing of the processor 31. The display 34 displays the image (moving image or frame image) taken by the camera 5, a screen for receiving from the user an input of the label information related to the discharge state of the discharger 13, various types of information such as the progress of the machine learning for generating the learning model, and so forth.

The operation module 35 receives a user's operation and notifies the processor 31 of the received operation. By way example, the operation module 35 receives a user's operation through an input device such as a mechanical button or a touch panel provided on a surface of the display 34. Further, the operation module 35 may be, for example, an input device such as a mouse or keyboard, and these input devices may be configured to be provided separately from the information processing device 3.

Further, the storage 32 may be an external storage device connected to the information processing device 3. The information processing device 3 may be a multi-computer including a plurality of computers, or may be a virtual machine virtually constructed by software. Further, the information processing device 3 is not limited to the above configuration, and may include, by way of example, a reading module configured to read information stored in a portable recording medium, or may not include, for example, the display 34 and the operation module 35.

In addition, in the information processing device 3 according to the present exemplary embodiment, the processor 31 reads and executes the program 32a stored in the storage 32, thereby allowing an image acquisition module 31a, a data expansion module 31b, a training data generation module 31c, a learning processor 31d, a display processor 31e, and the like to be implemented in the processor 31 as software functional modules. In the drawings, functional modules that perform the processing related to the generation of the training data and the generation of the learning model are shown as functional modules of the processor 31, and functional modules related to a processing other than these are omitted.

The image acquisition module 31a performs a processing of acquiring the image data of the discharger 13 of the substrate processing apparatus 1 taken by the camera 5 by communicating with the camera 5 through the communication module 33. In the present exemplary embodiment, the camera 5 is configured to acquire a moving image by performing imaging operations about several tens of times per second. The image data obtained by the image acquisition module 31a may be in the form of a moving image, or may be in the form of a still image (frame image) included in the moving image. The image acquisition module 31a repeatedly performs the acquisition of the image from the camera 5, and stores the image acquired from the camera 5 in the training data storage 32b. Further, the image acquisition module 31a repeatedly performs the acquisition of the image from the camera 5 while the substrate processing is being performed, thereby obtaining time-series frame images of the discharger 13.

The data expansion module 31b performs a processing of increasing the number of frame images by performing data expansion based on the moving image (a plurality of frame images in time series) taken by the camera 5. In the present exemplary embodiment, the data expansion module 31b performs the data expansion by extracting a frame image at a certain time point and a frame image at the next time point among the plurality of frame images in time series included in the moving image, and generating a frame image corresponding to a time point between these two time points. The data expansion module 31b stores the generated frame image in the training data storage 32b.

The training data generation module 31c performs a processing of generating training data for machine learning based on the frame image included in the moving image acquired by the image acquisition module 31a and the frame image generated by the data expansion module 31b through the data expansion. By way of example, the training data generation module 31c performs a processing of receiving from the user an input of label information to be included in the training data for performing supervised machine learning. The training data generation module 31c displays, for example, the frame image on the display 34 and receives an input of label information indicating the discharge state of the discharger 13 captured in the displayed frame image based on the user's operation through the operation module 35. The training data generation module 31c stores the displayed frame image and the label information input by the user in the training data storage 32b while matching them to each other. The training data generation module 31c receives an input of label information for each of a plurality of frame images including the frame image included in the moving image acquired by the image acquisition module 31a and the frame image generated by the data expansion module 31b through the data expansion, and a dataset including multiple sets of the frame image and the corresponding label information is used as the training data. In addition, when generating training data for non-supervised learning that does not include label information, the training data generation module 31c does not perform reception of an input of label information, but simply collects the frame image included in the moving image acquired by the image acquisition module 31a and the frame image generated by the data expansion module 31b through the data expansion into a dataset, and this dataset is used as training data.

The learning processor 31d performs a processing of performing a machine learning processing using the training data stored in the training data storage 32b, thereby generating a learning model that performs prediction or the like based on the frame image. The learning processor 31d performs, for example, supervised machine learning by using the training data in which the frame image is matched with the corresponding label information indicating the discharge state, and generates a learning model that receives the frame image as an input and outputs information indicating the discharge state of the discharger 13 captured in this frame image. The learning model may adopt such a configuration as a convolutional neural network (CNN) or a deep neural network (DNN), but is not limited thereto, and may have any of various configurations. The learning processor 31d performs the machine learning processing by using an existing method such as, but not limited to, a stochastic gradient descent method or a backpropagation method. Since the configuration of the learning model and the machine learning method for generating the learning model are existing technologies, a detailed description thereof will be omitted in the present exemplary embodiment.

The display processor 31e performs a processing of displaying various types of characters, images, etc. on the display 34. In the present exemplary embodiment, the display processor 31e displays, for example, the moving image acquired by the image acquisition module 31a or the frame image included in this moving image on the display 34. In addition, in order to receive an input of the discharge state of the discharger 13 captured in the displayed frame image, the display processor 31e displays, for example, a plurality of selection items indicating the discharge state on the display 34. The user may perform an operation of selecting, among the plurality of selection items displayed on the display 34, one that is suitable as the discharge state of the discharger 13 captured in the displayed frame image, and the information processing device 3 may receive this operation through the operation module 35, thereby receiving an input of label information on the discharge state of the frame image. In addition, the display processor 31e also displays information such as, but not limited to, the number of repetitions of learning or an evaluation value of the learning model, on the display 34 as the progress of the machine learning processing.

### <Training Data Generation Processing>

The information processing device 3 according to the present exemplary embodiment performs processing of generating training data for machine learning to generate a learning model based on frame images included in a moving image of the discharger 13 of the substrate processing apparatus 1 taken by the camera 5. Here, the information processing device 3 can increase the training data by performing data expansion processing based on the plurality of frame images included in the moving image.

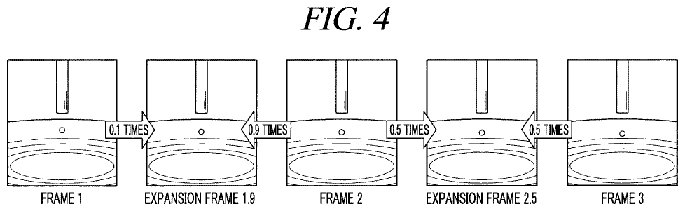

FIG. 4 is a schematic diagram for explaining data expansion performed by the information processing device 3 according to the present exemplary embodiment. In this drawing, the frame images included in the moving image taken by the camera 5 are indicated in the order of time series as “frame 1,” “frame 2,” and “frame 3” with the names “frame+integer value.” In addition, in this drawing, new frame images generated by the information processing device 3 through the data expansion of these frame images are indicated by the names of “expansion frame+decimal value,” such as expansion frame 1.9 and expansion frame 2.5.

The information processing device 3 extracts two frame images: a frame image at a certain time point included in the moving image and the next frame image in the time series following this frame image. The information processing device 3 calculates an average value of corresponding pixels of the two extracted frame images, and generates, as an expansion frame image, a frame image with the calculated average value as a pixel value. In the example shown in this drawing, an expansion frame 2.5 is generated based on an average value of the frames 2 and 3.

In addition, the information processing device 3 may generate an expansion frame image by calculating a weighted average value instead of a simple average value. In the example shown in FIG. 4, an expansion frame 1.9 is generated based on an average value calculated by assigning a weight of 1 to 9 to the frame 1 and the frame 2. The information processing device 3 may generate an expansion frame image by, for example, randomly assigning a weight to two frame images extracted from the moving image and calculating a weighted average value. Furthermore, when generating an expansion frame image from two frame images, the information processing device 3 may employ various methods, such as linear interpolation or cubic interpolation, instead of calculating an average value or a weighted average value.

The information processing device 3 stores the frame image included in the original moving image and the expansion frame image generated by expanding this frame image as a dataset in the training data storage 32b. This dataset may be used as training data for performing non-supervised machine learning to generate a learning model such as an autoencoder, for example. In addition, the information processing device 3 according to the present exemplary embodiment generates, as training data for generating a learning model that performs prediction such as classification or regression based on images by performing supervised machine learning, a dataset in which label information that becomes a correct answer value of prediction is assigned to each frame image (including the original frame image and the expansion frame image). The information processing device 3 acquires the label information assigned to each frame image through an input from the user.

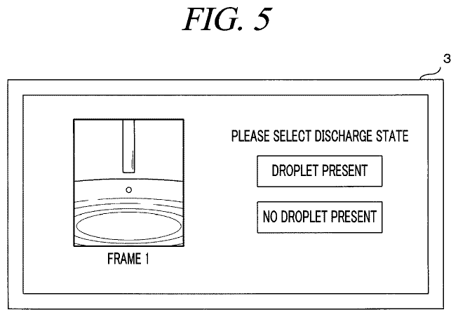

FIG. 5 is a schematic diagram showing an example of a label information input screen displayed by the information processing device 3 according to the present exemplary embodiment. In this example, it is assumed that the user performs, for a frame image of the discharger 13 of the substrate processing apparatus 1, a so-called annotation operation in which the user selects either the label of “Droplet present” for a state in which a droplet is falling from the discharger 13 onto a substrate as a processing target or the label of “No droplet present” for a state in which no droplet is falling. However, this is nothing more than an example, and any label information may be assigned to the frame image.

In the present exemplary embodiment, the information processing device 3 appropriately extracts one frame image from the plurality of frame images (the original frame image and the expansion frame image), for example, and displays it in the left area of the label information input screen, and displays a message string of “Please select discharge state” and buttons respectively assigned with the label of “Droplet present” and the label of “No droplet present” in a vertical direction in the right area of the same screen. The user is capable of inputting label information for the frame image by performing a click operation or a touch operation on one of the button “Droplet present” and the button “No droplet present” through the use of the operation module 35 such as a mouse or a touch panel, for example. The information processing device 3 receives a selection of the label information by the user according to the operation on one of the buttons, and stores the selected label information in the training data storage 32b while matching it with the frame image displayed on the label information input screen. The information processing device 3 may sequentially receive the input of label information from the user for the plurality of frame images, and store the received label information in the training data storage 32b, thereby using this dataset, in which sets of the frame image and the label information are collected, as training data.

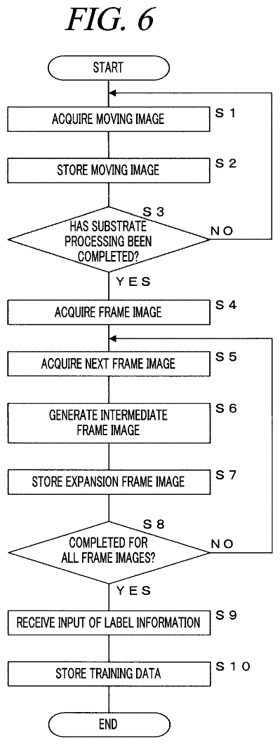

FIG. 6 is a flowchart showing an example sequence of a training data generation processing performed by the information processing device 3 according to the present exemplary embodiment. In the present exemplary embodiment, the image acquisition module 31a of the processor 31 of the information processing device 3 performs communication with the camera 5 through the communication module 33 to acquire the data of the moving image taken by the camera 5 when the substrate processing is being performed in the substrate processing apparatus 1 (process S1). The image acquisition module 31a stores the moving image data (frame images included therein) acquired in the process S1 in the training data storage 32b of the storage 32 (process S2). The image acquisition module 31a determines whether the substrate processing by the substrate processing apparatus 1 has been completed (process S3). If the substrate processing is not completed (S3: NO), the image acquisition module 31a returns to the process S1, and repeats the acquisition and storage of the moving image until the substrate processing is completed. In addition, the determination on whether or not the substrate processing is completed may be performed by the information processing device 3 through, for example, communication with the substrate processing apparatus 1 or based on the moving image taken by the camera 5.

If the substrate processing is completed (S3: YES), the data expansion module 31b of the processor 31 acquires a frame image (for example, a first frame image) of a certain time point from the plurality of frame images included in the moving image data stored in the process S2 (process S4). Also, the data expansion module 31b acquires the next frame image in the time series following the frame image acquired in the process S4 (process S5). The data expansion module 31b generates an intermediate frame image between the certain time point and the next time point by calculating, for example, an average value of corresponding pixels for the frame image at the certain time point and the frame image at the next time point (process S6). The data expansion module 31b stores this expansion frame image generated in the process S6 in the training data storage 32b (process S7). The data expansion module 31b determines whether the data expansion has been completed for all the frame images acquired and stored in the processes S1 and S2 (process S8). If the data expansion has not been completed for all of the frame images (S8: NO), the data expansion module 31b returns to the process S5 to further acquire a frame image at the next time point, and repeats the same processing as described above.

When the data expansion is completed for all of the frame images (S8: YES), the training data generation module 31c of the processor 31 displays, for example, the label information input screen shown in FIG. 5 on the display 34, and performs reception of an input of label information for all the frame images including the frame images included in the moving image and the frame images generated by the data expansion (process S9). The training data generation module 31c stores the label information received in the process S9 in the training data storage 32b as training data while matching them with the corresponding frame images (process S10), and terminates the training data generation processing.

In the present exemplary embodiment, the information processing device 3 uses both the frame image included in the moving image and the expansion frame image generated by expanding this frame image as the training data. However, the present disclosure is not limited thereto. The information processing device 3 may use only the expansion frame image generated by performing data expansion on the original frame image as the training data.

### <Learning Model Generation Processing>

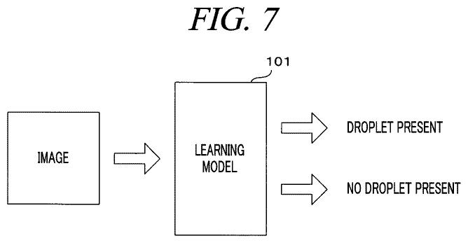

The information processing device 3 according to the exemplary embodiment of the present disclosure performs a processing of generating a learning model that makes predictions regarding the substrate processing by using the training data generated based on the moving image taken by the camera 5. FIG. 7 is a schematic diagram showing a configuration example of the learning model generated by the information processing device 3. In this example, a learning model 101 generated by the information processing device 3 is a learning model that receives an image of the discharger 13 of the substrate processing apparatus 1 as an input and classifies whether the discharge state of the discharger 13 is “droplet present” or “no droplet present.” This learning model 101 may employ a configuration of, for example, CNN. The learning model 101 outputs two values, one indicating the possibility that the discharge state of the discharger 13 is “droplet present” and the other indicating the possibility that the discharge state is “no droplet present,” based on the input of the image of the discharger 13, and the discharge state with the larger value becomes the classification result.

The information processing device 3 may generate the illustrated learning model 101 by performing supervised machine learning, using the training data generated in the training data generation processing described above, for example, the training data in which a frame image of the discharger 13 of the substrate processing apparatus 1 is matched with label information of “Droplet present” or “No droplet present.” In the supervised machine learning, the information processing device 3 inputs the frame image of the training data into the learning model 101, and updates internal parameters of the learning model 101 so that information output by the learning model 101 in response to the input approximates the label information of the training data, thereby generating the learning model 101.

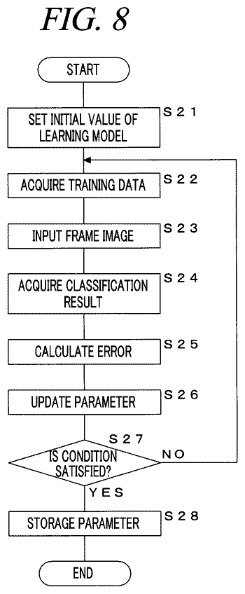

FIG. 8 is a flowchart showing an example sequence of a learning model generation processing performed by the information processing device 3 in the present exemplary embodiment. In this drawing, a sequence for generating the learning model 101 shown in FIG. 7 by performing supervised machine learning is shown. In the present exemplary embodiment, the learning processor 31d of the processor 31 of the information processing device 3 sets an initial value of an internal parameter for the learning model 101 having a previously set architecture of, e.g., CNN (process S21). The initial value of the internal parameter may be, by way of example, a pre-determined value, a randomly determined value, or a value of an internal parameter of the learning model 101 for which learning has been previously carried out to some extent.

The learning processor 31d acquires one training data stored in the training data storage 32b (process S22). The learning processor 31d inputs the frame image included in the training data acquired in the process S22 into the learning model 101 (process S23). The learning processor 31d obtains a classification result of “droplet present” or “no droplet present” output by the learning model 101 in response to the input of the process S23 (process S24). The learning processor 31d calculates an error of the classification result obtained in the process S24 based on the label information included in the training data obtained in the process S22 (process S25). The learning processor 31d updates the internal parameter of the learning model 101 by, for example, a backpropagation method based on the error calculated in the process S25 (process S26).

The learning processor 31d determines whether a condition for terminating the machine learning, such as a condition that the number of repetitions exceeds a threshold value or a condition that the prediction accuracy of the learning model 101 reaches a target value, has been achieved (process S27). If the termination condition has not been achieved (S27: NO), the learning processor 31d returns to the process S22 and repeats the above-described processing. If the termination condition has been achieved (S27: YES), on the other hand, the learning processor 31d stores the internal parameter of the learning model 101 in the model information storage 32c (process S28) and terminates the learning model generation processing.

In the present exemplary embodiment, the information output by the learning model 101 is set to be the two types of discharge states: “droplet present” and “no droplet present.” However, the present disclosure is not limited thereto. The learning model 101 may also be configured to output information indicating three or more types of discharge states.

For example, the learning model 101 may be configured to output information indicating four discharge states: “liquid column present,” “liquid column broken and falling,” “droplet present,” and “no liquid present.” The discharge state of “liquid column present” is a state in which a liquid is being continuously discharged from the discharger 13 and a lower end of the discharger 13 and a top surface of the substrate are connected by a columnar liquid (liquid column). The discharge state of “liquid column broken and falling” is a state immediately after the discharge of the liquid from the discharger 13 is stopped, and in this state, there is a space between the lower end of the discharger 13 and an upper end of the liquid column, and the liquid column stands on the top surface of the substrate. The discharge state of “droplet present” is a state in which no liquid column exists between the lower end of the discharger 13 and the top surface of the substrate, and one or more spherical liquids (droplets) are present. The discharge state of “no liquid present” is a state in which neither the liquid column nor the droplet is present between the lower end of the discharger 13 and the top surface of the substrate.

In addition, the learning model 101 may not be a classification model that classifies the discharge state but be a regression model that predicts a numerical value related to the discharge. By way of example, the learning model 101 may be configured to predict and output a numerical value such as the size or amount of a droplet captured in a frame image.

### SUMMARY

In the information processing system according to the present exemplary embodiment configured as described above, the information processing device 3 acquires a moving image of a substrate processing performed by the substrate processing apparatus 1, which is taken by the camera 5, and generates expansion data (expansion frame image) based on a frame image at a first time point included in the acquired moving image and a frame image at a second time point thereafter. In this way, in the information processing system according to the present exemplary embodiment, frame images for use in machine learning, etc., can be increased by using the expansion frame image generated by data expansion in addition to the frame image acquired from the moving image taken by the camera 5. Thus, it is expected to support image-based operation analysis for the substrate processing.

In addition, in the information processing system according to the present exemplary embodiment, the information processing device 3 generates expansion data by acquiring a moving image of the discharger 13 of the substrate processing apparatus 1 configured to discharge a liquid onto a substrate as a processing target. Accordingly, the information processing system according to the present exemplary embodiment is expected to generate expansion data for performing machine learning to generate the learning model 101 that determines the discharge state of the discharger 13 of the substrate processing apparatus 1.

Further, in the information processing system according to the present exemplary embodiment, the information processing device 3 generates expansion data based on the average value or the weighted average value of the frame image of the first time point and the frame image of the second time point. Accordingly, the information processing system according to the present exemplary embodiment is expected to generate the expansion data through easy calculation.

Additionally, in the information processing system according to the exemplary embodiment of the present disclosure, the information processing device 3 performs machine learning by using training data including the generated expansion data, thereby generating a learning model that outputs information on the state of the substrate processing from a frame image included in a moving image of the substrate processing apparatus 1. In this way, the information processing system according to the present exemplary embodiment is expected to determine the state of the substrate processing by using the generated learning model, and to implement a control over the substrate processing according to the determined state.

### Second Exemplary Embodiment

In the first exemplary embodiment described above, the training data generated by the information processing device 3 is assumed to generate the learning model 101 that receives an image as an input. However, training data generated by the information processing device 3 according to a second exemplary embodiment aims to generate a learning model that receives feature data generated based on an image as an input.

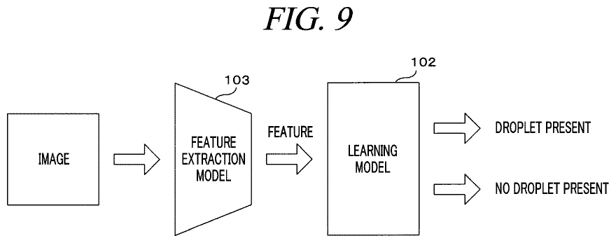

FIG. 9 is a schematic diagram showing a configuration example of a learning model generated by the information processing device 3 according to the second exemplary embodiment. A learning model 102 according to the second exemplary embodiment is a learning model that receives a feature of an image of the discharger 13 of the substrate processing apparatus 1 as an input, and classifies whether the discharge state of the discharger 13 is either “droplet present” or “no droplet present.” The information processing device 3 according to the second exemplary embodiment is equipped with a feature extraction model 103 that extracts a feature from a frame image included in a moving image taken by the camera 5. The feature extraction model 103 is a learning model that is generated by performing machine learning in advance in the information processing device 3 or another device, and information such as internal parameters is stored in the model information storage 32c. In addition, since the learning model that converts an image into a feature is an existing technology, a detailed description of the configuration of the learning model and the learning method will be omitted here.

The information processing device 3 according to the second exemplary embodiment generates, as training data for performing machine learning of the learning model 102 shown in FIG. 9, data in which a feature extracted by the feature extraction model 103 from the frame image included in the moving image taken by the camera 5 is matched with label information indicating whether the discharge state of the discharger 13 captured in the original frame image is “droplet present” or “no droplet present”. The information processing device 3 acquires the moving image taken by the camera 5, acquires the frame image included in the acquired moving image, inputs the acquired frame image into the feature extraction model 103, and acquires a feature output by the feature extraction model 103. In this way, the information processing device 3 is capable of obtaining a plurality of features respectively corresponding to a plurality of frame images included in the moving image.

In addition, the information processing device 3 according to the second exemplary embodiment increases the features used as the training data by performing data expansion on the plurality of features extracted from the frame images included in the moving image. The data expansion on the features may be performed by a method such as calculation of an average value or a weighted average value, linear interpolation, cubic interpolation, or the like, the same as in the data expansion on the frame images performed in the first exemplary embodiment. By way of example, when the feature extraction model 103 converts an image into an N-dimensional (N is a natural number) feature vector, the information processing device 3 can obtain a data-expanded N-dimensional feature vector by calculating, for each of N feature values at a certain time point and N feature values at the next time point, the average of each corresponding pair.

The information processing device 3 according to the second exemplary embodiment displays the same screen as the label information input screen shown in FIG. 5 on the display 34, and receives an input of label information for the frame image from the user to create training data in which the received label information is matched with the feature extracted from the displayed frame image. Also, in order to receive an input of label information for the certain feature generated by the data expansion, the information processing device 3 may generate a display image by calculating an average value of two frame images corresponding to two features that have served as the basis for creating the certain feature, and may display the generated image on the label information input screen.

In addition, in the case of generating training data for performing non-supervised machine learning, the information processing device 3 may use, as training data, a dataset including a feature extracted from the frame image included in the moving image and a feature generated by data expansion based on the extracted feature.

In the information processing system according to the second exemplary embodiment configured as described above, the information processing device 3 converts a frame image included in the moving image into feature data, and generates expansion data based on the feature data of the frame image at a first time point and the feature data of the frame image at a second time point. In this way, the information processing system according to the present exemplary embodiment is capable of generating a learning model that predicts the state of the substrate processing or the like based on the features, by using the generated expansion data. Thus, the information processing system according to the present exemplary embodiment is expected to support image-based operation analysis for the substrate processing, or the like.

Here, since the other configurations of the information processing system according to the second exemplary embodiment are the same as those of the information processing system according to the first exemplary embodiment, the same parts will be assigned the same reference numerals, and detailed descriptions thereof will be omitted.

### Third Exemplary Embodiment

In the information processing system according to the first and second exemplary embodiments described above, when the substrate processing apparatus 1 performs wet etching as the substrate processing, the discharger 13 is imaged by the camera 5 to acquire the moving image thereof, and by performing data expansion on the frame images included in the acquired moving image, training data is generated. However, the target of the data expansion and the training data generation is not limited to the moving image of the discharger 13 taken during the wet etching.

In the substrate processing performed by the substrate processing apparatus 1, a processing such as etching or ion implantation is performed by using a resist formed on the processing target substrate as a mask, and then, the unnecessary resist is removed from the substrate. For the removal of the resist, a removing liquid such as sulfuric acid hydrogen peroxide mixture (SPM), which is a mixture of sulfuric acid and hydrogen peroxide, is used, and the removing liquid is discharged from the discharger 13 onto the processing target substrate while being heated to a high temperature in order to enhance the ability to remove the resist. In the information processing system according to a third exemplary embodiment, when the substrate processing apparatus 1 performs the removal of the resist formed on the substrate, the discharger 13 that is discharging the removing liquid is imaged by the camera 5 to acquire a moving image thereof, and by performing data expansion on frame images included in the acquired moving image, training data is generated.

The information processing device 3 according to the third exemplary embodiment performs the data expansion on the frame images included in the moving image of the discharger 13 taken when the resist removing processing is performed, thereby increasing the training data. In addition, the information processing device 3 according to the third exemplary embodiment may convert, like the information processing device 3 according to the second exemplary embodiment, a frame image into a feature and perform data expansion on this feature. The data expansion of the frame image or the feature may be performed by a method such as calculation of an average value or a weighted average value, linear interpolation, cubic interpolation, or the like.

In the resist removing processing, since the high-temperature removing liquid is discharged, vapor is generated inside the chamber 11, and there is a concern that the visibility of the moving image taken by the camera 5 may be reduced by being affected by the vapor. Since the expansion frame image generated by the information processing device 3 based on the frame image included in the moving image is generated by the data expansion based on the average value or the like, it is expected that the influence of the vapor in the frame image will be reduced. To achieve this effect, in the information processing device 3 according to the third exemplary embodiment, the frame image included in the moving image taken by the camera 5 may not be in the training data, and only the expansion frame image generated by performing the data expansion based on the frame image may be included in the training data.

In addition, since the other configurations of the information processing system according to the third exemplary embodiment are the same as those of the information processing systems according to the first and second exemplary embodiments, the same parts will be assigned the same reference numerals, and a detailed description thereof will be omitted here.

Further, although the wet etching has been described as an example of the substrate processing in the first and second exemplary embodiments and the removal of the resist has been described as an example of the substrate processing in the third exemplary embodiment, the generation of the expansion data, etc., by the information processing system according to the exemplary embodiments is not limited to these types of substrate processing, and can be applied to various other types of substrate processing. In addition, the portion of the substrate processing apparatus 1 imaged by the camera 5 is not limited to the discharger 13, and various other portions of the substrate processing apparatus 1 may be imaged.

The exemplary embodiments disclosed herein should be considered to be illustrative in all aspects and not anyway limiting. The scope of the present disclosure is defined by the scope of the claims, not by the meaning described above, and is intended to include all modifications within the scope and meaning equivalent to the scope of the claims.

The matters described in the exemplary embodiments can be combined with each other. In addition, it is to be understood that any combination of features described in the independent and dependent claims may be made, regardless of the manner in which the claims are referenced. In addition, although the claims are described using a format (multiple dependent claim format) in which a claim refers to two or more other claims, the present disclosure is not limited thereto. A format (multiple-multiple dependent claim format) may also be employed in which a multiple dependent claim depends on at least one other multiple dependent claim.

According to the exemplary embodiment, it is expected to support the image-based operation analysis for the substrate processing.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

We claim:

1. A non-transitory computer-readable recording medium having stored thereon a computer program that, in response to execution by circuitry, causes the circuitry to perform a method comprising:
acquiring a moving image of a substrate processing apparatus; and
generating expansion data based on a frame image of a first time point and a frame image of a second time point later than the first time point, which are included in the acquired moving image.

2. The non-transitory computer-readable recording medium of claim 1, the method further comprising:
acquiring a moving image of a discharger of the substrate processing apparatus, which is configured to discharge a liquid onto a substrate as a processing target.

3. The non-transitory computer-readable recording medium of claim 1, the method further comprising:
generating the expansion data based on an average of the frame image of the first time point and the frame image of the second time point.

4. The non-transitory computer-readable recording medium of claim 1, the method further comprising:
converting the frame image of the first time point and the frame image of the second time point into feature data, and
generating the expansion data based on feature data converted from the frame image of the first time point and feature data converted from the frame image of the second time point.

5. The non-transitory computer-readable recording medium of claim 4, the method further comprising:
generating the expansion data based on an average of the feature data of the first time point and the feature data of the second time point.

6. The non-transitory computer-readable recording medium of claim 3, the method further comprising:
generating the expansion data based on a weighted arithmetic mean.

7. The non-transitory computer-readable recording medium of claim 4, the method further comprising:
generating the expansion data based on a weighted arithmetic mean.

8. The non-transitory computer-readable recording medium of claim 5, the method further comprising:
generating the expansion data based on a weighted arithmetic mean.

9. The non-transitory computer-readable recording medium of claim 1,
wherein a learning model, in which information related to a state of the substrate processing apparatus is output from a frame image included in the moving image of the substrate processing apparatus, is generated by machine learning using the generated expansion data.

10. A data generation method performed by an information processing device including circuitry, the data generation method comprising:
acquiring a moving image of a substrate processing apparatus; and
generating expansion data based on a frame image of a first time point and a frame image of a second time point later than the first time point, which are included in the acquired moving image.

11. An information processing device, comprising:
circuitry configured to:
acquire a moving image of a substrate processing apparatus; and
generate expansion data based on a frame image of a first time point and a frame image of a second time point later than the first time point, which are included in the acquired moving image.

12. The non-transitory computer-readable recording medium of claim 1,
wherein the frame image of the first time point and the frame image of the second time point are converted into feature data.

13. The non-transitory computer-readable recording medium of claim 2,
wherein the expansion data is generated based on a weighted arithmetic mean.

14. The data generation method of claim 10, further comprising:
acquiring a moving image of a discharger of the substrate processing apparatus, which is configured to discharge a liquid onto a substrate as a processing target.

15. The data generation method of claim 10, further comprising:
generating the expansion data based on an average of the frame image of the first time point and the frame image of the second time point.

16. The data generation method of claim 10, further comprising:
converting the frame image of the first time point and the frame image of the second time point into feature data, and
generating the expansion data based on feature data converted from the frame image of the first time point and feature data converted from the frame image of the second time point.

17. The data generation method of claim 16, further comprising:
generating the expansion data based on an average of the feature data of the first time point and the feature data of the second time point.

18. The data generation method of claim 15, further comprising:
generating the expansion data based on a weighted arithmetic mean.
